(19) United States
(12) Patent Application Publication
(10) Pub. No.: US 2026/0013073 A1
(43) Pub. Date: Jan. 8, 2026

(54) Direct to Component Thermal Expansion Compensation for Heat Exchangers

(71) Applicant: Fabric8Labs, Inc., San Diego, CA (US)

(72) Inventors: Ian Winfield, Oceanside, CA (US); Timothy Ouradnik, San Diego, CA (US); Michael Matthews, Encinitas, CA (US); Joseph Madril, San Diego, CA (US); Guillermo Romero, Phoenix, AZ (US)

(21) Appl. No.: 19/255,200

(22) Filed: Jun. 30, 2025

Related U.S. Application Data
(60) Provisional application No. 63/667,120, filed on Jul. 2, 2024.
(60) Provisional application No. 63/694,053, filed on Sep. 12, 2024.
(60) Provisional application No. 63/695,162, filed on Sep. 16, 2024.
(60) Provisional application No. 63/696,759, filed on Sep. 19, 2024.
(60) Provisional application No. 63/697,403, filed on Sep. 20, 2024.
(60) Provisional application No. 63/697,993, filed on Sep. 23, 2024.
(60) Provisional application No. 63/725,483, filed on Nov. 26, 2024.

(51) Int. Cl. H05K 7/20

(52) U.S. Cl. CPC H05K 7/20263

(57) ABSTRACT

Described herein are heat exchangers and heat source assemblies, which may be fabricated using electrochemical additive manufacturing (ECAM). A heat exchanger comprises a support structure and a conductive seed layer having a different composition than the support structure and forming a heat-transferring surface on the heat source. The heat exchanger further comprises a heat-exchanging portion comprising heat transfer extensions. The heat transfer extensions comprise first extension ends, second extension ends, and sidewalls extending between the first extension ends and the second extension ends and forming an opening for circulating a heat transfer fluid through the heat exchanger. The first extension ends are electrochemically deposited to the heat-transferring surface and form a heat-exchanging surface. Any dimension of each extension end may be less than a critical dimension, determined by adhesion, CTE mismatch, and temperature fluctuations.

### CROSS-REFERENCE TO RELATED APPLICATIONS

This application claims the benefit under 35 U.S.C. § 119 (e) of U.S. Provisional Patent Application 63/694,053 (Docket No. F8L-044-PRO) filed on 2024 Sep. 12 and also claims the benefit under 35 U.S.C. § 119 (e) of U.S. Provisional Patent Application 63/697,993 (Docket No. F8L-026-PRO) filed on 2024 Sep. 23, U.S. Provisional Patent Application 63/667,120 (Docket No. F8L-041-PRO) filed on 2024 Jul. 2, U.S. Provisional Patent Application 63/725,483 (Docket No. F8L-048-PRO2) filed on 2024 Nov. 26, U.S. Provisional Patent Application 63/695,162, (Docket No. F8L-045-PRO) filed on 2024 Sep. 16, U.S. Provisional Patent Application 63/696,759, (Docket No. F8L-046-PRO), filed on 2024 Sep. 19, and U.S. Provisional Patent Application 63/697,403 (Docket No. F8L-047-PRO), filed on 2024 Sep. 20, all of which are incorporated herein by reference in their entirety for all purposes.

### BACKGROUND

Fluid cooling for electronics (e.g., in data centers) and other applications may be categorized based on the coolant's interaction with heat sources: direct (when the coolant comes in direct contact) and indirect (using intermediary heat exchangers, such as a cold plate, heat pipe, or vapor chamber, to transfer heat from the processor to the coolant). Indirect cooling avoids direct contact between the coolant and electronics, which makes it more attractive for various applications.

Heat exchangers (e.g., heat sinks, cooling units) are conventionally manufactured using extrusion, stamping, die casting, bonding, folding, forging, skiving, and machining. However, these methods put various limitations on the geometry, materials, and other design considerations. For example, a typical heat sink formed by skiving has a base and multiple parallel fins that are made from the same material (e.g., copper) as the base and form uniform openings (e.g., microchannels). While copper has excellent thermal properties (e.g., particularly suitable for fins), copper also has a high coefficient of thermal expansion (CTE) making it particularly challenging to thermally bond to various low-CTE materials (e.g., silicon used in most electronics). This bonding may necessitate the use of high-performance and/or thicker thermal interface materials (TIM) (to accommodate the CTE mismatch), which is not desirable from the thermal transfer and spacing perspectives. Furthermore, conventional heat exchanges tend to have limited cooling capabilities due to their geometries and materials.

### SUMMARY

Described herein are heat exchangers and heat source assemblies, which may be fabricated using electrochemical additive manufacturing (ECAM). A heat exchanger comprises a support structure and a conductive seed layer having a different composition than the support structure and forming a heat-transferring surface on the heat source. The heat exchanger further comprises a heat-exchanging portion comprising heat transfer extensions. The heat transfer extensions comprise first extension ends, second extension ends, and sidewalls extending between the first extension ends and the second extension ends and forming an opening for circulating a heat transfer fluid through the heat exchanger. The first extension ends are electrochemically deposited to the heat-transferring surface and form a heat-exchanging surface. Any dimension of each extension end may be less than a critical dimension, determined by adhesion, CTE mismatch, and temperature fluctuations.

Clause 1. A heat exchanger for use on a heat source comprising a heat-transferring surface, the heat exchanger comprising: a base comprising a heat-receiving surface for thermal coupling to the heat-transferring surface; and a heat-exchanging portion onto and attached to the base and comprising heat-exchanging extensions, wherein: the heat-exchanging extensions comprise heat-exchanging surfaces, a combination of the heat-exchanging surfaces and the base forms opening for flowing a heat transfer fluid through the heat exchanger, the opening extend to the base such that the heat transfer fluid is able to directly interface the base and the heat-exchanging surfaces while flowing through the heat exchanger, and an average coefficient of thermal expansion (CTE) of the base is closer to an average CTE of the heat source than an average CTE of the heat-exchanging portion.

Clause 2. The heat exchanger of clause 1, wherein the average CTE of the base is less than the average CTE of the heat-exchanging portion.

Clause 3. The heat exchanger of clause 1, wherein the base comprises tungsten.

Clause 4. The heat exchanger of clause 1, wherein the base further comprises copper, forming an alloys with tungsten.

Clause 5. The heat exchanger of clause 1, wherein the base comprises one or more materials selected from the group consisting of silicon carbide (SiC), silver-diamond composite (AgD), and copper-diamond composite (CuD).

Clause 6. The heat exchanger of clause 1, wherein the heat-exchanging portion is formed from copper.

Clause 7. The heat exchanger of clause 1, wherein the heat-exchanging portion comprises a uniform material composition.

Clause 8. The heat exchanger of clause 1, wherein: the heat transfer extensions comprise first extension ends and second extension ends such that the heat-exchanging surfaces extend between the first extension ends and the second extension ends, and a material composition of the heat transfer extensions varies between the first extension ends and the second extension ends.

Clause 9. The heat exchanger of clause 8, wherein the material composition of the heat transfer extensions gradually changes between the first extension ends and the second extension ends.

Clause 10. The heat exchanger of clause 8, wherein the material composition of the heat transfer extensions changes in a step fashion between the first extension ends and the second extension ends.

Clause 11. The heat exchanger of clause 1, wherein a cross-sectional shape of the heat transfer extensions with a plane parallel to the base is selected from the group consisting of an oval, a rectangle, a trapezoid, and a triangle.

Clause 12. The heat exchanger of clause 1, wherein the heat transfer extensions have a height (H) of 30-200 micrometers.

Clause 13. The heat exchanger of clause 1, wherein the heat transfer extensions have a thickness (T) of 30-200 micrometers.

Clause 14. The heat exchanger of clause 1, wherein the heat transfer extensions have an average pitch (P) of 50-250 micrometers.

Clause 15. The heat exchanger of clause 1, wherein the heat source is selected from the group consisting of a central processing unit (CPU), a graphical processing unit (GPU), an application-specific integrated circuit (ASIC), a field-programmable gate array (FPGA), a chipset, a power amplifier, a memory module, and a power management integrated circuit (IC).

Clause 16. The heat exchanger of clause 1, further comprising a cover sealed against the base and forming a cavity thereby between, wherein the heat-exchanging portion extends within the cavity such that the opening is part of the cavity.

Clause 17. The heat exchanger of clause 16, wherein the cover directly interfaces the heat-exchanging portion.

Clause 18. The heat exchanger of clause 16, further comprising a cover gasket positioned between the cover and the heat-exchanging portion.

Clause 19. A heat source assembly comprising: a heat source comprising a heat-transferring surface; and a heat exchanger comprising a base and a heat-exchanging portion, wherein: the base comprising a heat-receiving surface mechanically adhered to the heat-transferring surface, the heat-exchanging portion is electrochemically deposited on and attached to the base and comprises heat-exchanging extensions, the heat-exchanging extensions comprise heat-exchanging surfaces, a combination of the heat-exchanging surfaces and the base forms opening for flowing a heat transfer fluid through the heat exchanger, the opening extends to the base such that the heat transfer fluid directly interfaces the base and the heat-exchanging surfaces while flowing through the heat exchanger, and an average coefficient of thermal expansion (CTE) of the base is closer to an average CTE of the heat source than an average CTE of the heat-exchanging portion.

Clause 20. The heat source assembly of clause 19, further comprising a thermal interface positioned between the base and the heat source and comprising one or more materials selected from the group consisting of silver epoxy and solder.

Clause 21. A heat exchanger for use on a heat source, the heat exchanger comprising: a support structure and a conductive seed layer having a different composition than the support structure and forming a heat-transferring surface on the heat source; a heat-exchanging portion comprising heat transfer extensions, wherein: the heat transfer extensions comprise first extension ends, second extension ends, and sidewalls extending between the first extension ends and the second extension ends and forming an opening for circulating a heat transfer fluid through the heat exchanger, and the first extension ends are electrochemically deposited to the heat-transferring surface and form a heat-exchanging surface.

Clause 22. The heat exchanger of clause 21, wherein any dimension of each of the first extension ends within a plane of the heat-exchanging surface is less than a critical dimension, determined by calculating adhesion between the first extension ends and the heat-transferring surface, a coefficient of thermal expansion (CTE) of the heat source at the heat-transferring surface, a coefficient of thermal expansion (CTE) of the heat transfer extensions at the first extension ends, and a design temperature fluctuation for the heat exchanger.

Clause 23. The heat exchanger of clause 21, wherein the heat-exchanging portion comprises copper.

Clause 24. The heat exchanger of clause 21, wherein the heat-exchanging portion comprises a uniform material composition.

Clause 25. The heat exchanger of clause 21, wherein a material composition of the heat transfer extensions varies between the first extension ends and the second extension ends.

Clause 26. The heat exchanger of clause 25, wherein the material composition of the heat transfer extensions gradually changes between the first extension ends and the second extension ends.

Clause 27. The heat exchanger of clause 25, wherein the material composition of the heat transfer extensions changes in a step fashion between the first extension ends and the second extension ends.

Clause 28. The heat exchanger of clause 21, wherein the heat-exchanging portion and the conductive seed layer have same material composition.

Clause 29. The heat exchanger of clause 21, wherein the heat-exchanging portion and the conductive seed layer have different material composition.

Clause 30. The heat exchanger of clause 21, wherein the support structure comprises tungsten.

Clause 31. The heat exchanger of clause 30, wherein the support structure further comprises copper, forming an alloys with tungsten.

Clause 32. The heat exchanger of clause 21, wherein the heat source is selected from the group consisting of a central processing unit (CPU), a graphical processing unit (GPU), an application-specific integrated circuit (ASIC), a field-programmable gate array (FPGA), a chipset, a power amplifier, a memory module, and a power management integrated circuit (IC).

Clause 33. The heat exchanger of clause 21, wherein the conductive seed layer has a thickness of less than micrometers.

Clause 34. The heat exchanger of clause 22, wherein the critical dimension is less than micrometers.

Clause 35. The heat exchanger of clause 21, wherein: the heat transfer extensions comprise first extension ends for attaching the heat exchanger to the heat source, the first extension ends are separated by gaps providing access to the opening and positioned within a plane defined by the first extension ends, and an area ratio of the first extension ends to the gaps is less than 25%.

Clause 36. The heat exchanger of clause 21, wherein the heat-exchanging portion further comprises an interconnecting bridge electrochemically deposited onto each of the second extension ends while partially enclosing the opening.

Clause 37. The heat exchanger of clause 21, wherein the first extension ends have a cross-sectional shape within a plane of the heat-exchanging surface selected from the group consisting of an oval a rectangle, a trapezoid, and a triangle.

Clause 38. The heat exchanger of clause 21, wherein the first extension ends and the second extension ends have same shape.

Clause 39. The heat exchanger of clause 21, wherein the first extension ends and the second extension ends have same size.

Clause 40. The heat exchanger of clause 21, wherein the first extension ends have smaller sizes than the second extension ends.

Clause 41. A method of fabricating a heat exchanger for use on a heat source comprising a heat-transferring surface using electrochemical additive manufacturing (ECAM), the method comprising: submerging a build plate comprising a deposition surface into an electrolyte, wherein the build plate comprises one or more components selected from the group consisting of a base and the heat source; submerging a printhead into the electrolyte proximate to the deposition surface, the printhead comprises a set of pixelated electrodes and electrode-array drivers; and selectively activating an electrode subset from the set of pixelated electrodes using the electrode-array drivers thereby generating an ionic flow through the electrolyte between the electrode subset and a portion of the deposition surface aligned with the electrode subset thereby electrochemically depositing a heat-exchanging portion comprising heat transfer extensions, wherein an average coefficient of thermal expansion (CTE) of the base is closer to an average CTE of the heat source than an average CTE of the heat-exchanging portion, wherein the base comprising a heat-receiving surface for thermal coupling to a heat-transferring surface of a heat source.

Clause 42. The method of clause 41, wherein: the build plate comprises the base and the heat source; and the method further comprises thermally coupling the heat-receiving surface of the base to the heat-transferring surface of the heat source.

Clause 43. The method of clause 42, wherein thermally coupling the heat-receiving surface of the base to the heat-transferring surface of the heat source comprises positioning a thermal interface between the heat-receiving surface and the heat-transferring surface.

Clause 44. The method of clause 42, wherein thermally coupling the heat-receiving surface of the base to the heat-transferring surface of the heat source comprises mechanically attaching the base to the heat source.

Clause 45. The method of clause 41, wherein the build plate comprises the heat source.

Clause 46. The method of clause 45, wherein the heat source is selected from the group consisting of a central processing unit (CPU), a graphical processing unit (GPU), an application-specific integrated circuit (ASIC), a field-programmable gate array (FPGA), a chipset, a power amplifier, a memory module, and a power management integrated circuit (IC).

Clause 47. The method of clause 45, further comprising, prior to submerging the build plate into the electrolyte, method comprises forming a conductive seed layer on the base.

Clause 48. The method of clause 47, wherein forming the conductive seed layer on the base comprises one or more techniques selected from the group consisting of sputtering, electroless electroplating, and thermal bonding.

Clause 49. The method of clause 41, further comprising, prior to selectively activating the electrode subset, designing a shape of the heat exchanger and developing a set of deposition maps corresponding to the shape of the heat exchanger, wherein the electrode subset is activated based on a deposition map in the set of deposition maps.

Clause 50. The method of clause 41, further comprising, after submerging the build plate and submerging the printhead and before selectively activating the electrode subset, registering a horizontal position of the build plate relative to the printhead using a mapping process and based on a shape of the build plate.

Clause 51. The method of clause 41, further comprising replacing the electrolyte between the printhead and the build plate.

Clause 52. The method of clause 51, wherein the electrolyte is replaced with the electrolyte having a different composition.

Clause 53. The method of clause 41, wherein the average CTE of the base is less than the average CTE of the heat-exchanging portion.

Clause 54. The method of clause 41, wherein: the base is formed from tungsten; and the heat-exchanging portion is formed from copper.

Clause 55. The method of clause 41, wherein the heat-exchanging portion comprises a uniform material composition.

Clause 56. The method of clause 41, wherein: the heat transfer extensions comprise first extension ends and second extension ends such that the heat-exchanging surfaces extend between the first extension ends and the second extension ends, and a material composition of the heat transfer extensions varies between the first extension ends and the second extension ends.

Clause 57. The method of clause 56, wherein the material composition of the heat transfer extensions gradually changes between the first extension ends and the second extension ends.

Clause 58. The method of clause 41, wherein a cross-sectional shape of the heat transfer extensions with a plane parallel to the base is selected from the group consisting of an oval, a rectangle, a trapezoid, and a triangle.

Clause 59. The method of clause 41, wherein the heat transfer extensions have a height (H) of 30-200 micrometers.

Clause 60. The method of clause 41, wherein the heat transfer extensions have an average pitch (P) of 50-250 micrometers.

These and other embodiments are described further below with reference to the figures.

### BRIEF DESCRIPTION OF THE DRAWINGS

The included drawings are for illustrative purposes and serve only to provide examples of possible structures and operations for the disclosed inventive systems, apparatus, and methods. These drawings in no way limit any changes in form and detail that may be made by one skilled in the art without departing from the spirit and scope of the disclosed implementations.

FIGS. 1A and 1B are side and top cross-sectional views of a heat source assembly comprising a heat exchanger thermally coupled to a heat source, in accordance with some examples.

FIG. 1C is a side cross-sectional view of a heat source assembly and a corresponding CTE profile, in accordance with some examples.

FIG. 2 is a side cross-sectional view of another example of a heat source assembly and a corresponding CTE profile.

FIG. 3A is a side cross-sectional view of yet another example of a heat source assembly and a corresponding CTE profile.

FIGS. 3B and 3C illustrate two examples of the first extension ends.

FIGS. 4A and 4B are side and top views of a heat source assembly comprising four heat sources, each thermally coupled to a corresponding heat-exchanging portion, and an interconnecting structure formed together with the heat-exchanging portions, in accordance with some examples.

FIG. 5 is a process flowchart corresponding to a method for fabricating a heat exchanger, in accordance with some examples.

FIG. 6A is a schematic illustration of an ECAM system for fabricating heat exchangers, in accordance with some examples.

FIG. 6B is the top view of a printhead comprising a set of pixelated electrodes, in accordance with some examples.

FIG. 6C is a schematic expanded view of a portion of the ECAM system (in FIG. 6A) illustrating electrolyte between the printhead and build plate, in accordance with some examples.

FIG. 6D is a schematic block diagram illustrating different components of the electrolyte, in accordance with some examples.

### DETAILED DESCRIPTION

### Introduction

Various issues with thermal interface materials (TIMs) in heat source assemblies, identified above, may be addressed using novel designs of heat exchangers. For purposes of this disclosure, a TIM layer that uses a material with a high flexibility (to accommodate the CTE mismatch) but a low heat transfer coefficient may be viewed as a “low-performance TIM”. On the other hand, a “high-performance TIM” has a high heat transfer coefficient, which is more desirable from the heat transfer perspective but may not provide sufficient mechanical properties. Another factor, in addition to the flexibility and heat transfer, is the thickness of a TIM layer. Problems that may be encountered include separation of the heat source from the heat exchanger, cracking of the heat source and/or the heat exchanger, migration of TIM, etc.

The novel designs of heat exchangers address these temperature fluctuations and the use of materials with different CTEs in various ways. For example, a heat exchanger portion (e.g., its base plate) that faces (or even interfaces, e.g., without using an intermediate TIM) a heat source may be formed from a material that has a different CTE (closer to the CTE of the heat source) than the rest of the heat exchanger. In the same or other examples, a heat exchanger portion that interfaces with a heat source may have an interfacing footprint that limits any mechanical stresses (generated during temperature changes) below a critical threshold. Furthermore, various designs of heat exchangers (e.g., geometries, compositions, etc.) enabled by fabricating these heat exchangers using techniques such as ECAM are within the scope. For example, ECAM may be used to electrodeposit structures (having complex and/or variable shapes) onto substrates with high thermal conductivity (e.g., to improve the overall cold plate performance). In other words, the cold-plate designs enabled by ECAM benefit from low CTEs, high thermal conductivities, or both. For example, copper-diamond and copper-encapsulated-graphite are both low CTE materials that also have high thermal conductivities. High thermal conductivity baseplates (e.g., made from the above-referenced materials) improve the performance over that of pure copper by improving heat transfer into the coolant and overall lowering temperature (Tmax).

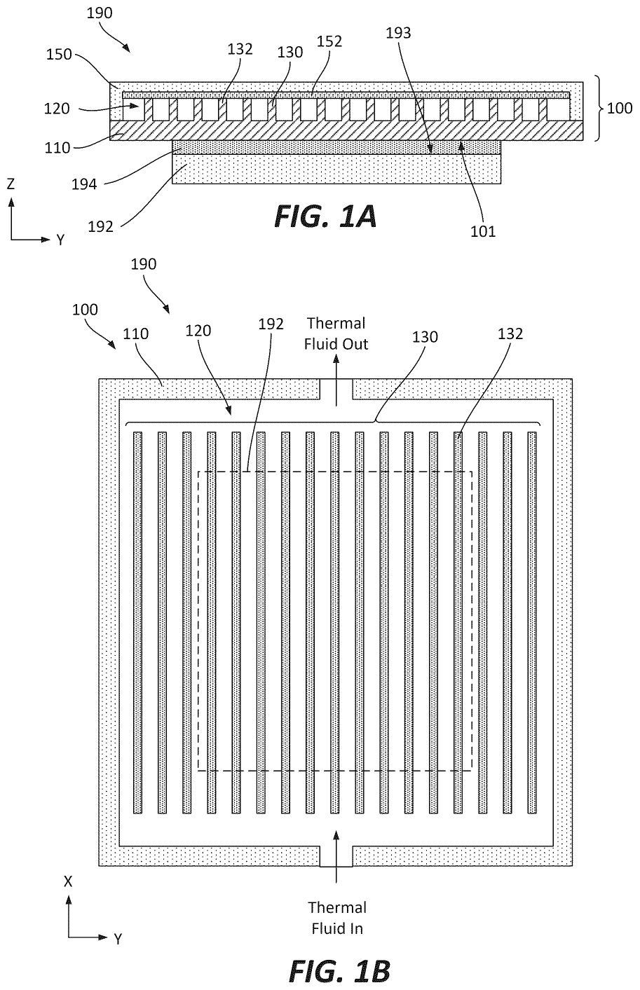

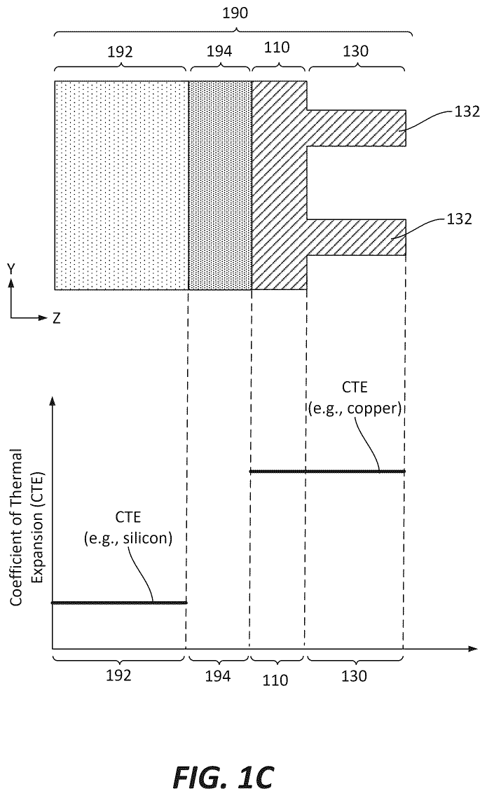

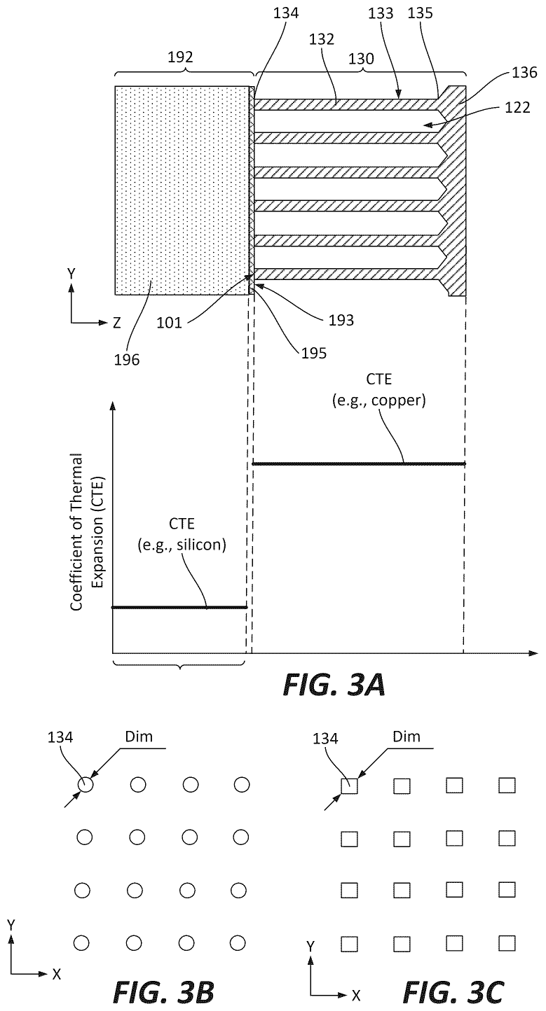

FIGS. 1A and 1B are side and top cross-sectional views of an example heat source assembly 190 comprising a heat exchanger 100 thermally coupled to a heat source 192 (with heat-transferring surface 193), in accordance with some examples. In the illustrated examples, this thermal coupling is provided by an optional thermal interface 194, which (if present) may be formed from a TIM or, more specifically, a high-performance TIM. A heat exchanger 100 comprises a base 110 (e.g., comprising a heat-receiving surface 101) and a heat-exchanging portion 130, thermally coupled to the base 110. In some examples, heat exchanger 100 also comprises a cover 150 forming (together with the base 110) a cavity 120, in which the heat-exchanging portion 130 is positioned. The cover 150 may directly interface/contact the heat-exchanging portion 130 (e.g., as shown in FIG. 3C), may be separated from the heat-exchanging portion 130 by a cover gasket 152 as shown in FIG. 1A (e.g., to present bypass flow), or may be spaced apart from the heat-exchanging portion 130 by a gap (e.g., as shown in FIG. 3B). The cavity 120 may be used for circulating various fluids (e.g., liquids, gases, mixtures of liquids and gases, etc.). For example, FIG. 1B illustrates a fluid inlet and a fluid outlet. The fluid flows within the cavity 120 (from the fluid inlet to the fluid outlet) while absorbing heat from the heat-exchanging portion 130. Specifically, the heat-exchanging portion 130 may comprise heat transfer extensions 132 (e.g., shown as rectangular walls in FIG. 1B) that come in contact with the cooling fluid, while also being thermally coupled with the base 110. In some examples, the fluid also comes in direct contact with the base 110. Furthermore, the immersive cooling, in which the fluid comes in direct contact with the heat source 192 is also within the scope (e.g., the base 110 may have openings, or the heat exchanger 100 may not include a base as shown in FIG. 3A and described below).

The heat-exchanging portion 130 may be attached to or, even, monolithic with the base 110, e.g., as shown in FIG. 1A. Alternatively, the heat-exchanging portion 130 may be supported on (e.g., monolithic with) the cover 150, which may be referred to as a “reverse” configuration. It should be noted that even in this “reverse” configuration, the heat-exchanging portion 130 is thermally coupled to the base 110 (e.g., through direct contact or some intermediate structure). In some examples, a reverse heat exchanger may be attached to the heat source 192 with an edge seal (e.g. gasket, brazing, soldering, etc.) that effectuates adhesion between the heat source 192 and seals in any heat exchanging fluid. Additional design aspects are described below with reference to various figures.

A thermal interface 194 (e.g., a TIM) may be used to accommodate the CTE mismatch between the heat source 192 (e.g., a die) and the heat exchanger 100.

However, the thermal interface 194 is optional. For example, FIG. 3A illustrates a “direct to die”/“direct to heat source” example, in which the heat exchanger 100 may directly interface the heat source 192 (without any intermediate structures, such as a thermal interface 194). Specifically, the CTEs of the heat source 192 and the heat exchanger 100 are sufficiently close and/or when the interface between these two components is sufficiently small (such that the CTE mismatch does not generate excessive stresses). Furthermore, these CTE-matching and minimal-interface features allow the use of different types of thermal interfaces 194 (e.g., a TIM with a high heat transfer coefficient, a thin TIM layer, etc.). For example, a base 110 and, in some examples, at least a portion of the heat-exchanging portion 130 that interfaces the base 110 may be formed from various materials that have a CTE closer matching that of the heat source 192. Some examples of suitable materials and their respective CTEs are presented in the table below. For example, various copper-tungsten (CuW) alloys or even tungsten (without any copper) may be used for the base 110. As a reference, the tungsten's CTE (4.5×10⁻⁶/° C.) is closer to silicon's CTE than to pure copper's CTE. The heat-exchanging portion 130 may be formed from copper or similar alloys. In some examples, the composition of the heat-exchanging portion 130 may change as the heat-exchanging portion 130 protrudes away from the base 110.

Specifically, FIG. 1C is a side cross-sectional view of a heat source assembly 190 and a corresponding CTE profile, in accordance with some examples. In this example, the base 110 and heat-exchanging portion 130 are made from the same material (e.g., copper) that has a significant CTE mismatch with the materials (e.g., silicon) of the heat source 192 thereby requiring a relatively thick and low-quality thermal interface 194. This thermal interface 194 acts as a thermal barrier.

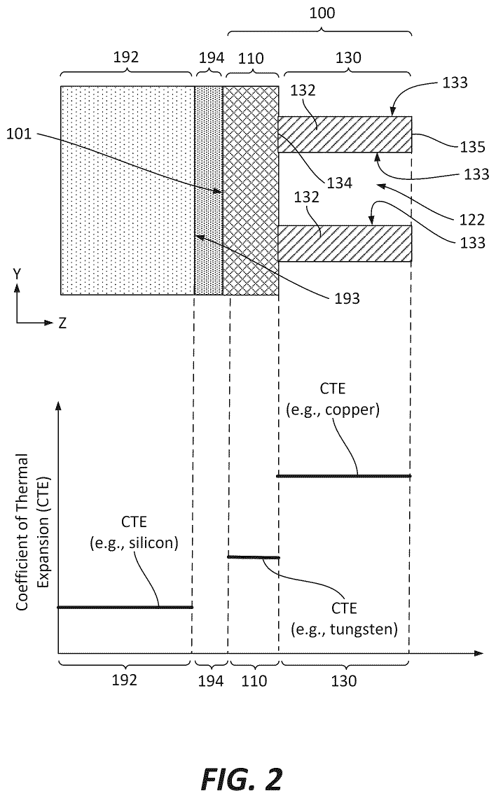

FIG. 2 is a side cross-sectional view of another example of a heat source assembly 190 and a corresponding CTE profile. In this example, the base 110 and heat-exchanging portion 130 are made from different materials, e.g., the base 110 is made from tungsten, while the heat-exchanging portion 130 is made from copper. The lower CTE mismatch (than in the example of FIG. 1C) may allow a much thinner/more thermally conductive thermal interface 194 (or no thermal interface 194 at all) thereby improving the cooling of the heat source 192.

Overall, with a lower CTE mismatch between the heat source 192 and the base 110, a high-performance TIM may be used. Any flexing or other deformation of the heat-exchanging portion 130 and the cover 150 has a much less impact on the interface between the heat source 192 and the base 110 (e.g., a cold plate) or, more specifically, the base 110. It should be noted that one or more (e.g., all) of the base 110, heat-exchanging portion 130, and cover 150 may be fabricated using techniques such as electrochemical additive manufacturing (ECAM).

Specifically, ECAM may be used to deposit structures (e.g., a heat-exchanging portion 130 formed from copper or other metal alloys) onto other metals, tungsten, or a copper-tungsten alloy (e.g., used for a base 110). For example, a copper-tungsten base 110 may be used as a cathode, and a heat-exchanging portion 130 or, more specifically, heat transfer extensions 132 (e.g., fins) are deposited onto the base 110. In some examples, other low-CTE substrates (e.g., silicon (Si)), ceramic substrates (e.g. silicon nitride (Si₃N₄), silicon carbide (SiC)), diamond-containing metal matrix materials (e.g., silver-diamond composite (AgD), copper-diamond composite (CuD)) may be used. For electrically non-conductive substrates, metallization may be performed (e.g., using sputtering/physical vapor deposition (PVD), electroplating (electroless), and thermal/direct bonding) prior to ECAM deposition.

Furthermore, high-surface-area heat features may enhance performance in both single-phase fluid cooling and two-phase fluid cooling applications, by virtue of high surface area and higher heat transfer coefficient of the complex structure, relative to a typical straight channel.

FIG. 2 is a schematic illustration of a heat source assembly 190 comprising a heat exchanger 100 as well as a heat source 192 and a thermal interface 194, in accordance with some examples. It should be noted that a heat exchanger 100 may be a standalone component (e.g., prior to thermally coupling to the heat source 192). Furthermore, thermal interface 194 is an optional component in the heat source assembly 190, e.g., the heat exchanger 100 may be directly interfacing the heat source 192 (without any intermediate components). For example, a heat exchanger 100 may be electrochemically formed directly on the heat source 192 (e.g., when the heat source 192 has a conductive surface or this conductive surface is formed on the heat source 192 and may become a part of the heat exchanger 100).

Various examples of the heat source 192 are within the scope, e.g., a central processing unit (CPU), a graphical processing unit (GPU), an application-specific integrated circuit (ASIC), a field-programmable gate array (FPGA), a chipset, a power amplifier, a memory module, and a power management integrated circuit (IC). In some examples, the heat source 192 is a multilayered structure comprising one or more of an integrated heat spreader (IHS), its own thermal interface material (TIM), a semiconductor die, a substrate, a set of solder balls/bumps, (e.g., organized as a ball-grid array (BGA)), and a motherboard (MB). An IHS may also be referred to as a lid. However, in some examples, a heat source 192, which may be a chip, can be de-lidded.

The thermal interface 194 (when present) may be formed from thermal greases, thermal pads (e.g., silicone), thermal tapes, thermal gels, thermal adhesives (e.g., epoxies, silver epoxies, etc.), solders, etc. For example, a thermal paste/grease may not bond but remain in a semi-liquid or gel-like state. A thermal pad may be formed from a solid soft material that conforms to the surfaces when pressure is applied. A thermal pad may not create a permanent bond but may stick slightly due to surface adhesion. A liquid metal may form a stronger physical connection with the metals (especially copper and aluminum) through wetting and minor alloying effects (without creating true chemical bonds). Adhesive TIMs are specialized TIMs, such as thermal epoxies, that bond surfaces together permanently and are often used in industrial applications where a heatsink must stay attached without mechanical fasteners. In general, TIMs with a high thermal conductivity and minimal thickness are desirable (to reduce the thermal resistance). However, various manufacturing constraints may impact the minimal possible thickness.

Referring to FIG. 2, a heat exchanger 100 comprises a base 110 and a heat-exchanging portion 130. Base 110 comprises a heat-receiving surface 101 for thermal coupling to the heat-transferring surface 193. The heat-exchanging portion 130 is electrochemically deposited on and attached to the base 110 and comprises heat-exchanging extensions 132. As such, the heat-exchanging portion 130 may be viewed as monolithic with the base 110 or growth-rooted on the base 110.

Referring to FIG. 2, the heat-exchanging extensions 132 comprise heat-exchanging surfaces 133, which may be also referred to in this example as sidewalls. A combination of the heat-exchanging surfaces 133 and the base 110 forms openings 122 for flowing a heat transfer fluid through the heat exchanger 100. These opening 122 may be also referred to as channels, spaces, and gaps. Various examples of heat transfer fluid are within the scope such as water, propylene glycol mixtures, refrigerants, etc. These openings 122 extend to the base 110 such that the heat transfer fluid can directly interface the base 110 and the heat-exchanging surfaces 133 while flowing through the heat exchanger 100.

Referring to FIG. 2, the average CTE of the base 110 is closer to the average CTE of the heat source 192 than the average CTE of the heat-exchanging portion 130. For example, the heat source 192 may be formed from silicon with a CTE of 2.6×10⁻⁶/° C. The base 110 may be formed from tungsten with a CTE of 4.5×10⁻⁶/° C. The heat-exchanging portion 130 may be formed from copper with a CTE of 16.5×10⁻⁶/° C. Tungsten's CTE is closer (than copper's CTE) to the silicon's CTE. As such, the base 110 is operable as a CTE buffer, like a thermal interface 194, which may reduce or eliminate the need for this thermal interface 194. It should be also noted that tungsten has a high electrical conductivity, which enables electrochemical deposition of heat-exchanging portion 130 on the base 110. Additional material examples are presented below.

The following table provides examples of different materials suitable for heat source 192, heat-exchanging portion 130, and base 110.

| | | Electrical | |
|---|---|---|---|
| | | Conductivity | |
| Material | CTE/° C. | (S/m) | Applications |
| Silicon (undoped) | 2.6 × 10⁻⁶ | 1-10 × 10⁻³ | heat source (e.g., |
| | | | CPU, GPU) |
| Copper | 16.5 × 10⁻⁶ | ~5.96 × 10⁷ | heat-exchanging |
| | | | portion |
| Tungsten | 4.5 × 10⁻⁶ | ~1.79 × 10⁷ | base |
| Cu (90%)-W (10%) | 8.3 × 10⁻⁶ | ~5.0 × 10⁷ | base |
| Cu (70%)-W (30%) | 7.2 × 10⁻⁶ | ~3.8 × 10⁷ | base |
| Cu (50%)-W (50%) | 6.0 × 10⁻⁶ | ~2.5 × 10⁷ | base |
| Silicon Nitride | 2.5-3.5 × 10⁻⁶ | ~10⁻¹⁴ to 10⁻¹⁶ | heat source |
| (Si₃N₄) | | | |
| Silicon Carbide (SiC) | 3.7-4.5 × 10⁻⁶ | ~10⁴ to 10⁵ | base |
| Silver-Diamond | 6-8 × 10⁻⁶ | ~4.0-5.5 × 10⁷ | base/thermal |
| Composite (AgD) | | | interface |
| Copper-Diamond | 6-9 × 10⁻⁶ | ~3.5-5.0 × 10⁷ | base/thermal |
| Composite (CuD) | | | interface |

In some examples, the average CTE of the base 110 is closer to the average CTE of the heat source 192 than to the average CTE of the heat-exchanging portion 130. For example, the difference between tungsten's CTE (in the example above) and silicon's CTE is less than the difference between tungsten's CTE and copper's CTE (i.e., tungsten's CTE is closer to silicon's CTE than to copper's CTE). In further examples, the average CTE of the base 110 is less than the average CTE of the heat-exchanging portion 130.

In some examples, the base 110 and the heat-exchanging portion 130 are formed from different materials (e.g., to achieve the CTE difference). For example, the base 110 may be formed from one or more materials selected from the group consisting of tungsten, tungsten-copper, etc. The heat-exchanging portion 130 may be formed from one or more materials selected from the group consisting of copper, copper alloys, etc., One example of the stack formed by the heat source 192/base 110/heat-exchanging portion 130 is described above, i.e., silicon/tungsten/copper.

In some examples, the heat-exchanging portion 130 comprises a uniform material composition. For example, and with reference to FIG. 2, the opening-forming extensions 132 comprise the first extension ends 134 and the second extension ends 135 such that the heat exchanging surfaces 133 (e.g., sidewalls) extend between the first extension ends 134 and the second extension ends 135. The first extension ends 134 may interface (attached to/monolithic with) the base 110, while the second extension ends 135 may extend away from the base 110. In the above-referenced examples, the composition of the first extension ends 134 and the second extension ends 135 may be the same (e.g., both copper).

Alternatively, the composition of the heat transfer extensions 132 varies between the first extension ends 134 and the second extension ends 135, which may be referred to as compositionally-graded heat transfer extensions 132 or functionally-graded heat transfer extensions 132. This feature may be enabled by the ECAM process used to fabricate the heat exchanger 100 or, more specifically, to fabricate at least the heat-exchanging portion 130. For example, an electrolyte containing metal ions may be changed during the ECAM deposition. As such, different sub-layers used to form heat transfer extensions 132 (between the first extension ends 134 and the second extension ends 135) may have different compositions. In specific examples, the concentration of tungsten may decrease from the first extension ends 134 and the second extension ends 135, considering the macroscale.

In some examples, the cross-sectional shape of the heat transfer extensions 132 changes (for example, gradually) between the first extension ends 134 and the second extension ends 135. For example, the cross-sectional area of the first extension ends 134 may be greater than that of the second extension ends 135, e.g., to ensure the adhesion, promote the heat transfer through the heat-receiving surface 101, and promote the fluid flow between the heat transfer extensions 132. Alternatively, the cross-sectional area of the first extension ends 134 may be smaller than that of the second extension ends 135, e.g., to reduce the stress generated by the CTE mismatch at the heat-receiving surface 101 and temperature fluctuations (during the operation of the heat source assembly 190).

Referring to FIGS. 3B and 3C, the heat transfer extensions 132 may have various shapes. For example, the cross-sectional shape of the heat transfer extensions 132 with the plane parallel to the base 110 is selected from the group consisting of an oval (more specifically, a circle), a rectangle (e.g., as shown in FIG. 1B). These shapes may be specifically selected based on the coolant flow and heat transfer considerations.

### “Direct to Die”/“Direct to Heat Source” Examples

FIG. 3A illustrates a “direct to die”/“direct to heat source” example, in which a thermal interface (e.g., TIM) is not used and in which the heat-exchanging portion 130 may be directly bonded to the heat source 192 and, in some examples, formed on the heat-transferring surface 193 of the heat source 192 (e.g., using ECAM). Various examples of the heat source 192 (e.g., a die) are described above. In large semiconductor dies, a maximum “distance to neutral point” may be considered, generally measured from the center of the die to the outermost solder pad. This distance, combined with the CTE mismatch between the die and its packaging, can be used to predict the stress that will be caused when the assembly is subjected to temperature fluctuations. In some examples, a distance to a neutral point may be considered not from the center of the die, but from the center of an area where a heat-exchanging portion contacts the die to the outer diameter of the heat-exchanging portion.

Referring to FIG. 3A, in some examples, the CTE mismatch (between the heat source 192 and heat exchanger 100 or, more specifically, the heat-exchanging portion 130 of the heat exchanger 100) is compensated for by controlling the interface areas/maximum dimensions between the heat source 192 and the heat-exchanging portion 130. For example, any dimension of each of the first extension ends 134 within a plane of the heat-exchanging surface 101 is less than a critical dimension. This critical dimension is determined by the adhesion between the first extension ends 134 and the heat-transferring surface 193, a coefficient of thermal expansion (CTE) of the heat source 192 at the heat-transferring surface 193, a coefficient of thermal expansion (CTE) of the heat transfer extensions 132 at the first extension ends 134, and an operating temperature fluctuation for the heat exchanger 100. When each contact area or, more specifically, the largest dimension of each contact area is below this critical dimension, the stress caused by the CTE mismatch and the temperature changes does not exceed a critical threshold. It should be noted that this “the largest dimension of each contact area” corresponds to the maximum “distance to neutral point” concept described above, e.g., “the largest dimension of each contact area” for a circular shape (diameter) may be twice larger than the maximum “distance to neutral point” (radius).

Referring to FIG. 3A, in some examples, the heat-transferring surface 193 is formed by a conductive seed layer 195 formed from one or more conductive materials (e.g., metals, such as copper). Specifically, the conductive seed layer 195 may be considered a part of the heat source 192, which may also comprise a support structure 196, formed from a different material (e.g., a non-conductive material such as silicon) than the conductive seed layer 195. The conductive seed layer 195 allows the system to electrochemically form the heat transfer extensions 132 right onto the heat source 192. However, a conductive seed layer 195 is optional (e.g., when the support structure 196 is sufficiently conductive to initiate the electrochemical deposition).

Even though (1) the conductive seed layer 195 may be a continuous layer of the support structure 196 and (2) the CTE of the conductive seed layer 195 may be appreciably different from the CTE of the support structure 196, the thickness of the conductive seed layer 195 may be such that the mechanical stress caused by the CTE mismatch and temperature changes is less than the adhesion strength between the conductive seed layer 195 and the support structure 196. For example, the thickness of the conductive seed layer 195 may be between about 50-150 micrometers or, more specifically, 75-125 micrometers.

In some examples, the opening-forming extensions 132 comprise the first extension ends 134 for attaching the heat exchanger 100 to the heat source 192. The first extension ends 134 are separated by opening gaps providing access to opening 122 and positioned within a plane defined by the first extension ends 134. The area ratio of the first extension ends 134 to the opening gaps is less than 25%, less than 20%, or even less than 10%. Such a small level of direct contact between the opening-forming extensions 132 and the heat source 192 helps to compensate for the CTE mismatch (by reducing the overall mechanical stress generated at the interface during temperature changes).

Referring to FIG. 3A, in some examples, the heat-exchanging portion 130 further comprises an interconnecting bridge 136 monolithic with each of the second extension ends 135 and supporting the second extension ends 135 while partially enclosing the opening 122. Specifically, in heat source assembly 190, the heat transfer extensions 132 are positioned between the heat source 192 and the interconnecting bridge 136. The interconnecting bridge 136 may provide mechanical support to the heat transfer extensions 132 (in addition to the mechanical support provided by the heat source 192) thereby allowing the heat transfer extensions 132 to be smaller.

In some examples, the interconnecting bridge 136 is operable as a cover to fluidically isolate the opening 122 from the environment. The interface between the heat transfer extensions 132 and the interconnecting bridge 136 may not be orthogonal. For example, FIG. 3A shows gradual slopes, which may increase manufacturability, facilitate fluid flow, etc.

Referring to FIGS. 3B and 3C, in some examples, the first extension ends 134 have a cross-sectional shape within the plane of the heat-exchanging surface 101 selected from the group consisting of an oval, a rectangle, a trapezoid, a triangle, generic polygons, etc., In the same or other examples, the first extension ends 134 and the second extension ends 135 have the same shapes. Alternatively, the first extension ends 134 and the second extension ends 135 have different shapes. For example, different shapes may be used for controlling heat transfer and fluid dynamics.

In some examples, the first extension ends 134 and the second extension ends 135 have the same maximum sizes (e.g., both ends may have the same shape). As noted above, the maximum size of the first extension ends 134 defines the stress at the interface with the heat source 192. Alternatively, the first extension ends 134 have smaller sizes than the second extension ends 135.

In some examples, the heat transfer extensions 132 have the uniform/same composition between the first extension ends 134 and the second extension ends 135. Alternatively, the composition of the heat transfer extensions 132 varies between the first extension ends 134 and the second extension ends 135.

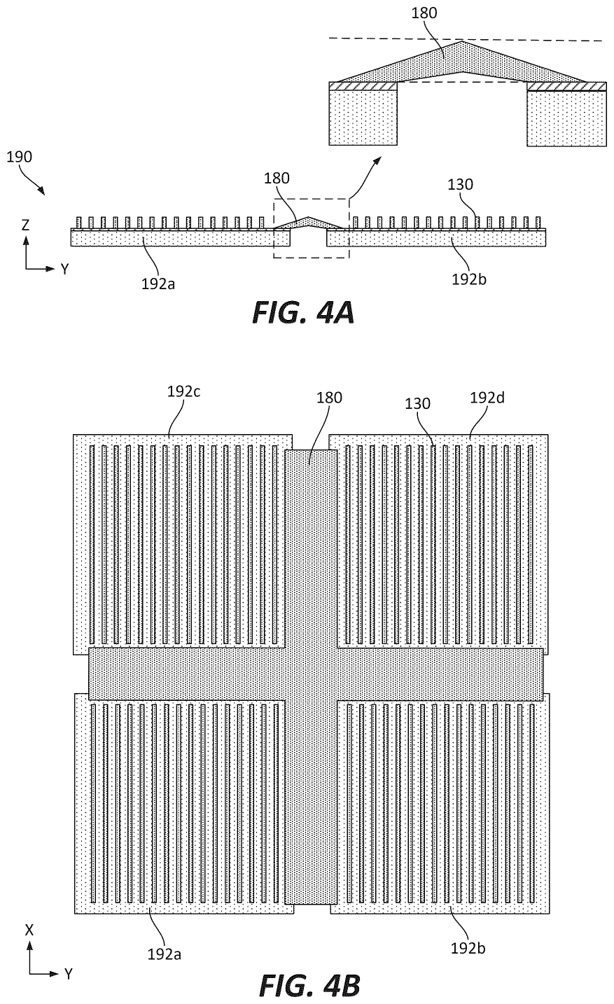

FIGS. 4A and 4B are side and top views of a heat source assembly 190 comprising four heat sources 192a-192d (e.g., dies), each thermally coupled to a corresponding heat-exchanging portion 130, and an interconnecting structure 180 formed together with these heat-exchanging portions 130, in accordance with some examples. The interconnecting structure 180 provides mechanical support to these heat sources 192a-192d with respect to each other, so that entire heat source assembly 190 may be handled as a unit. While the interconnecting structure 180 in FIG. 4A is shown with peaked top and bottom profiles (such structures may facilitate manufacturing, for example), other profiles including rectangular prisms, etc. are within the scope. For example, ECAM involves electroplating a layer over another conductive layer (operable as an electrode). The deposited layer may have a increased boundary (grow sideways) to a limited extent.

Various examples of a heat-exchanging portion 130 are within the scope. For example, a heat-exchanging portion 130 may be formed by two composite structures, which are stacked, in which these structures have different pitches, and in which openings extend perpendicular to other structures. The composite aspect may be related to the material composition and/or types of structures in different parts of the heat-exchanging portion 130 (e.g., unlike conventional structures formed by skiving). For example, these structural differences may be used to support two or more different/independent flow paths within the heat-exchanging portion 130 (with heat transferred from one fluid path/fluid to another). The total height of this stack/heat-exchanging portion 130 may be between 0.3-2 millimeters or, more specifically, 0.4-1 millimeters.

In another example, a heat-exchanging portion 130 is formed by interwoven composite wicks, which provide precise alignment between meshes and metallurgical bonds between these meshes. Such heat-exchanging portions 130 may be used for two-phase cooling, especially in vapor chamber or wicking applications where capillary action is beneficial. Such heat-exchanging portions 130 provide many nucleation sites and paths for bubbles to escape. Specifically, bubbles operate as thermal insulators, and when the bubbles get trapped, the heat transfer rate is reduced, which is not desirable.

Another example of a heat-exchanging portion 130 is a composite gyroid, which provides a high-surface-area-to-volume ratio and may be referred to as a triply periodic minimal surface (TPMS) structure. Such TPMS structures are mathematically defined surfaces that repeat periodically in three dimensions and have zero mean curvature at every point. These structures provide excellent mechanical strength, low density, and high surface-area-to-volume ratio. Some notable characteristics include a mean curvature that is zero, meaning the surface is balanced in terms of tension. The structure repeats in three-dimensional space, forming a continuous and interconnected network. A high strength-to-weight ratio and a high-surface-area feature are useful for heat exchanger applications. Some examples of TPMS structures include but are not limited to, gyroid (e.g., a highly interconnected and curved structure with no straight lines), Schwarz (a primitive and diamond-like TPMS surfaces), and lidinoid (e.g., a complex variation used in advanced material designs). TPMS structures may be specifically configured for the fluid flow dynamics, e.g., low-pressure drop (due to the lack of sharp edges) makes them ideal for compact cooling systems. The interconnected openings within a gyroid structure allow for better convective cooling. However, TPMS structures can not be produced by conventional methods (e.g., skiving), while ECAM is capable of producing the TPMS structures for heat-exchanging applications (e.g., EV battery cooling, microprocessors, and heat exchangers)

In some examples, functional grading is used for different parts of a multi-phase heat exchanger (e.g., a condenser region, evaporator region, and adiabatic region). For example, the lattice and/or structure density varies in a heat-exchanging portion 130 (such as from denser to more porous).

In some examples, a heat-exchanging portion 130 is formed by body-centered-cubic (BCC). A specific example of this type of heat-exchanging portion 130 is a composite body-centered-cubic (BCC). These types of heat-exchanging portion 130 have lattice structures that are optimized for “K/r”, with “K” being permeability, and “r” being effective pore radius. The “K/r” is a useful variable or parameter to understand the balance between the capillary pressure and permeability, i.e., how easily the fluid flows through something. These examples of a heat-exchanging portion 130 are suitable for wicking structures and 2-phase cooling.

### Examples of Methods for Fabricating Heat Exchangers

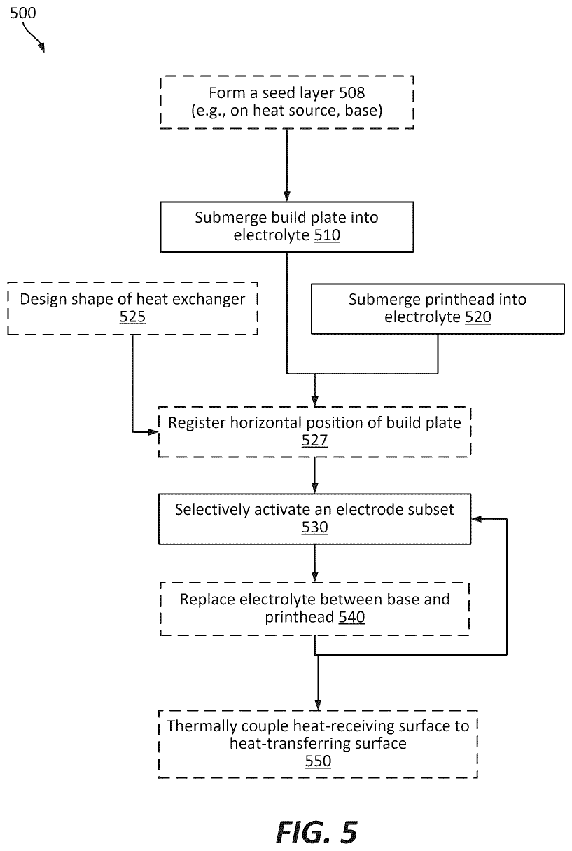

FIG. 5 is a process flowchart corresponding to method 500 for fabricating a heat exchanger 100 using electrochemical additive manufacturing (ECAM), in accordance with some examples. Various aspects of this method 500 enable precise, localized electrochemical deposition, providing enhanced control over the geometry and material composition of the heat exchanger 100 or, more specifically, of the heat-exchanging portion 130, allowing for the fabrication of complex (e.g., nonlinear) geometries that are not possible with conventional methods such as skiving.

Referring to FIG. 5, in some examples, method 500 comprises (block 510) submerging a build plate 650 comprising a deposition surface into an electrolyte 680. Various aspects of the electrolyte 680 (e.g., containing various metal ions used for fabricating a heat-exchanging portion 130) are described below. The build plate 650 comprises one or more components selected from the group consisting of a base 110 and a heat source 192. For example, the build plate 650 may comprise the base 110 such that the base 110 comprises a heat-receiving surface 101 for thermal coupling to the heat-transferring surface 193 and the deposition surface opposite of the heat-receiving surface 101.

Alternatively, the build plate 650 comprises the heat source 192, As noted above, the heat source 192 may be selected from the group consisting of a central processing unit (CPU), a graphical processing unit (GPU), an application-specific integrated circuit (ASIC), a field-programmable gate array (FPGA), a chipset, a power amplifier, a memory module, and a power management integrated circuit (IC). These examples may be referred to as “direct to die” deposition/“direct to heat source” deposition of the heat-exchanging portion 130. The base 110 may not be a part of the resulting heat exchanger 100.

Overall, the submersion of the build plate 650 into the electrolyte 680 creates the necessary environment for electrochemical deposition, e.g., providing ion exchange and material deposition while enabling precise control over the material composition at different locations on the deposition surface.

In some examples, prior to (block 510) submerging the build plate 650 into the electrolyte 680, method 500 comprises (block 508) forming a seed layer on the build plate 650 (e.g., a heat source 192 or, more specifically, a die). For example, the build plate 650 may initially have a surface that is not conductive, which would not allow electrochemical deposition. A seed layer may be deposited, e.g., using sputtering/physical vapor deposition (PVD), electroplating (electroless), and thermal/direct bonding. The seed layer is formed from a conductive material and, in turn, forms a deposition surface. Various examples of a seed layer are described above with reference to FIG. 3A.

Referring to FIG. 5, in some examples, method 500 comprises (block 520) submerging a printhead 610 into the electrolyte 680 and proximate to the deposition surface. As further described below, the printhead 610 comprises a set of pixelated electrodes 620 and electrode-array drivers 616. Specifically, these pixelated electrodes 620 allow for highly localized and selective material deposition. Unlike conventional electroplating techniques that apply a uniform current across an entire surface, the use of pixelated electrodes 620 enables spatial control over deposition, leading to complex geometries and fine structural features necessary for high-performance heat exchangers. This capability allows the formation of nonlinear geometries, specially configured fluidic pathways, and material composition that would be unattainable with traditional fabrication methods such as skiving.

Referring to FIG. 5, in some examples, method 500 further comprises registering (block 527) the horizontal position of the build plate 650 relative to the printhead 610 using a mapping process based on the shape of the build plate 650. This registering operation (block 527) is performed after (block 510) submerging the build plate 650 and (block 520) submerging the printhead 610 and before (block 530) selectively activating the electrode subset.

Referring to FIG. 5, in some examples, method 500 comprises (block 530) selectively activating an electrode subset from the set of pixelated electrodes 620 using the electrode-array drivers 616 thereby generating an ionic flow through the electrolyte 680 between the electrode subset and a portion of the deposition surface aligned with the electrode subset thereby electrochemically depositing a heat-exchanging portion 130. As noted above, the ability to control individual electrodes enables precision in material deposition thereby allowing complex geometries of the heat-exchanging portion 130, e.g., optimized heat transfer.

The operation represented by (block 530), i.e., selectively activating an electrode subset from the set of pixelated electrodes 620, may be repeated multiple times with different electrode subsets thereby changing the geometry/cross-section of the heat-exchanging portion 130 as it extends away from the build plate 650. ECAM is an additive manufacturing process, which deposits a new layer in each deposition cycle. The footprint of each layer depends on the subset of pixelated electrodes 620 activated during this cycle.

In some examples, prior to (block 530) selectively activating the electrode subset, method 500 comprises (block 525) designing the shape of the heat exchanger 100 and developing a set of deposition maps corresponding to the shape of the heat exchanger 100. For example, each deposition map represents one ECAM deposition cycle that forms a shaped deposit. Specifically, the deposit is a layer with a shape determined by the location of the activated electrode subset (with the thickness of the layer determined by the duration of the deposition cycle). As such, the shape of which layer is controlled by the corresponding deposition map, while the entire shape of the heat exchanger 100 or, more specifically, the shape of the heat-exchanging portion 130 is determined by the set of deposition maps. During the selectively activating operation (block 530), the electrode subset is activated based on a deposition map in the set of deposition maps.

In some examples, method 500 comprises (block 540) replacing the electrolyte 680 between the printhead 610 and build plate 650 or, more specifically, between the printhead 610 and a partially formed heat-exchanging portion 130. The electrolyte 680 may be replaced with a fresh electrolyte having the same composition (e.g., to remove gas bubbles, and replenish metal ions) or with an electrolyte having a different composition (e.g., having different metal ions).

In some examples, method 500 comprises (block 550) thermally coupling the heat-receiving surface 101 of the base 110 to the heat-transferring surface 193 of the heat source 192. For example, this thermal coupling operation may comprise positioning a thermal interface 194 between the heat-receiving surface 101 and the heat-transferring surface 193 (e.g., as shown in FIG. 2). Furthermore, the thermal coupling operation may comprise mechanically attaching the base 110 to the heat source 192. It should be noted that ECAM may be performed on a heat source 192 (e.g., depositing heat-exchanging extensions 132 directly on the heat-transferring surface 193 or depositing a base 110 on the heat-transferring surface 193). The heat source 192 may be sensitive to the electrolyte environment and, therefore, isolated from the electrolyte 680 during ECAM processing.

### ECAM System Examples

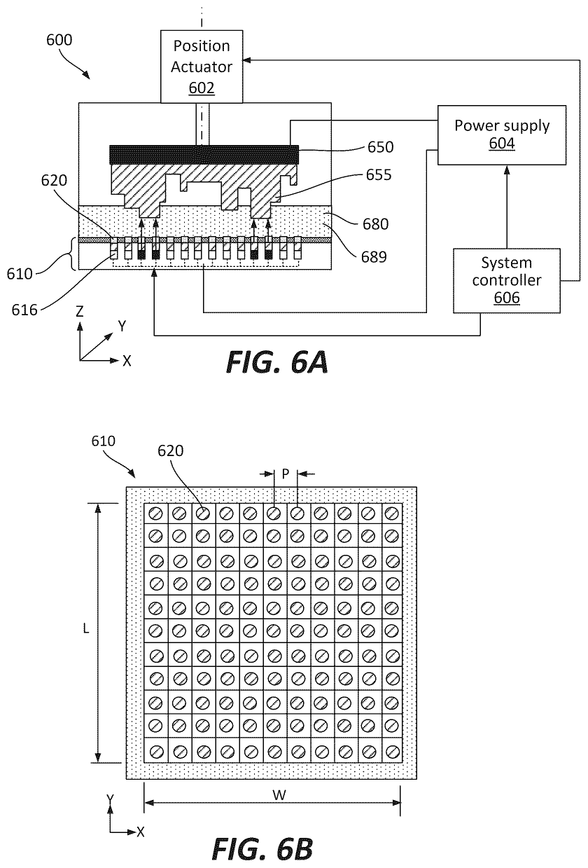

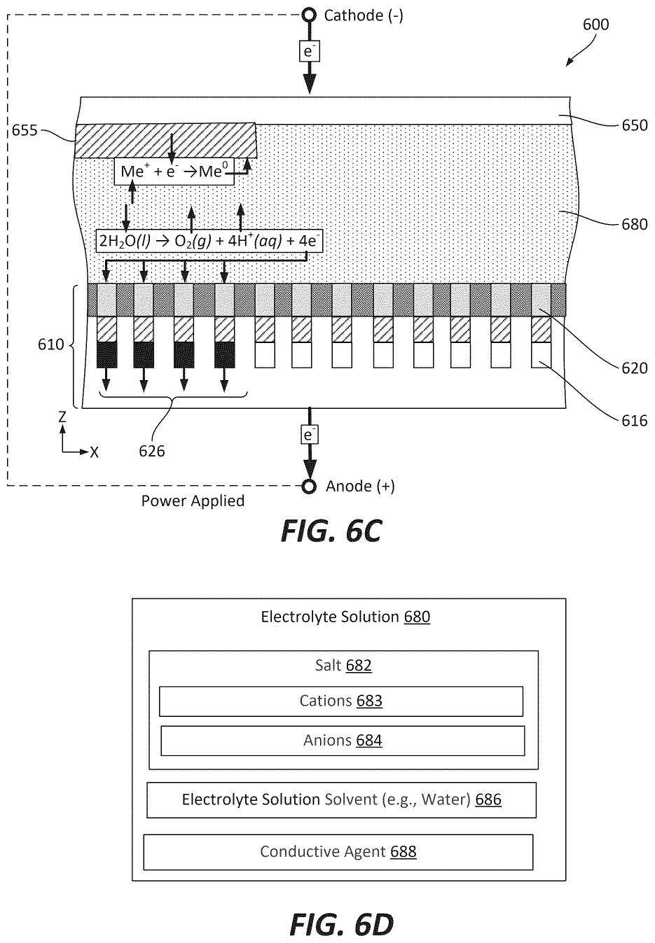

FIG. 6A is a schematic illustration of an ECAM system 600 used for depositing or, more specifically, electroplating material (e.g., copper deposit), in accordance with some examples. An ECAM system 600 may comprise a position actuator 602, a system controller 606, a deposition power supply 604, a printhead 610, and a build plate 650. In some examples, a build plate 650 is connected to the deposition power supply 604 and controllably supported relative to the ECAM printhead 610 (e.g., by position actuator 602).

An ECAM printhead 610 or simply a printhead 610 comprises a set of pixelated electrodes 620 and electrode-array drivers 616. Each of the electrode-array drivers 616 controls the current flow through a corresponding electrode in the set of pixelated electrodes 620 as well as the corresponding portion of the electrolyte 680 thereby causing the deposition on the corresponding surface of the material (e.g., copper deposit) on build plate 650.

A position actuator 602 can be mechanically coupled to the build plate 650 and used to change the positional relationship of the printhead 610 and build plate 650 (e.g., changing the gap between the printhead 610 and build plate 650 or, more specifically, the gap between the set of pixelated electrodes 620 and build plate 650, linearly moving and/or rotating one or both printhead 610 and build plate 650 within a plane parallel to the set of pixelated electrodes 620). While FIG. 6A illustrates the position actuator 602 coupled to the build plate 650, the position actuator may be coupled to the printhead 610 and/or the build plate 650. Other examples are also within the scope.

A system controller 606 is used for controlling the operations of various components. For example, FIG. 6A illustrates the system controller 606 that is communicatively coupled with the position actuator 602, deposition power supply 604, and electrode-array drivers 616. The system controller 606 can instruct the position actuator 602 to change the relative position of the printhead 610 and build plate 650. In the same or other examples, the system controller 606 can selectively instruct some electrode-array drivers 616 to provide current through a subset of pixelated electrodes 621 selected the set of pixelated electrodes 620 (e.g., based on the required deposition location).

During the operation, the ECAM system 600 also comprises electrolyte 680 comprising a source of cations (e.g., metal cations) that are reduced on build plate 650 (operable as a cathode during this operation) and form the material (e.g., copper deposit). More specifically, material (e.g., copper deposit) is deposited onto build plate 650 from the electrolyte 680 by flowing the electrical current between selected electrodes in the set of pixelated electrodes 620 and the build plate 650 as noted above. In some examples, further granularity is provided by controlling the current levels through each one of the electrode-array drivers 616. In other words, not only the current can be shut off through one or more electrode-array drivers 616 but different levels of current can flow through different electrode-array drivers 616 (and as a result through the corresponding electrodes in the set of pixelated electrodes 620).

Referring to FIG. 6B, a printhead 610 comprises a set of pixelated electrodes 620. These electrodes may be also referred to as microelectrodes (or micro-anodes), and/or pixels. This individually-addressable feature of the set of pixelated electrodes 620 allows the achievement of different deposition rates at different locations on build plate 650. The electrodes form a deposition grid, in which these electrodes may be offset relative to each other along the X-axis and Y-axis, each within a grid footprint. Rectangular grids may be characterized by a grid X-axis pitch (corresponding to the length of each grid region along the X-axis), grid Y-axis pitch (corresponding to the length of a grid region along the Y-axis), overall grid pitch (corresponding to the minimum of the grid X-axis pitch and the grid Y-axis pitch), and grid region area. In the same or other examples, one or both of the grid's X-axis pitch and the Y-axis pitch are 600 micrometers or less, 50 micrometers or less, or even 35 micrometers or less. Other example grids include triangular, hexagonal, or other patterns that partially or completely tessellate a surface. In some examples, the electrodes are formed/deposited from an insoluble conductive material, such as platinum group metals and their associated oxides, doped semiconducting materials, and carbon nanotubes. The shape of the electrodes can be round, rectangular, or other shapes. The area of the electrodes (the pixel size) is smaller (e.g., at least 6% smaller, at least 60% smaller, at least 20% smaller) than the grid footprint, thereby providing space between the electrodes. In some examples, the pitch is between 25 micrometers and 35 micrometers, while the pixel size is between 65 micrometers and 20 micrometers.

FIG. 6C is a schematic expanded view of a portion of ECAM system 600 illustrating electrolyte 680 between the printhead 610 and build plate 650, in accordance with some examples. FIG. 6D is a schematic block diagram illustrating different components of electrolyte 680. For example, electrolyte 680 may comprise salt 682, electrolyte solution solvent 686, and conductive agent 688. Salt comprises cations 683 and anions 684. Cations 683 can be in the form of metal ions, metal complexes, and the like. Some examples of cations 683 include metal cations (e.g., copper ions, nickel ions, tungsten ions, gold ions, silver ions, cobalt ions, chrome ions, iron ions, or tin ions), and other types of cations are within the scope. Some specific examples of salt 682 (feedstock ion sources) include but are not limited to copper sulfate, copper chloride, copper fluoroborate, copper pyrophosphate, nickel sulfate, nickel ammonium sulfate, nickel chloride, nickel fluoroborate, zinc sulfate, sodium thiocyanate, zinc chloride, ammonium chloride, sodium tungstate, cobalt chloride, cobalt sulfate, hydroxy acids, and aqua ammonia. In some examples, feedstock ion sources, or other sources of cations (e.g., salts) are referred to as material concentrates. Electrolyte solution solvent 686 can be water, which dissociates (2H2O(I)=>O2 (g)+4H+ (aq.)+4e−) on the electrodes that are activated during this operation. Specifically, the activated electrodes are connected to the deposition power supply. In some examples, electrolyte 680 comprises catholyte conductive agent 688, such as an acid (e.g., sulfuric acid, acetic acid, hydrochloric acid, nitric acid, hydrofluoric acid, boric acid, citric acid, and phosphoric acid). In some examples, electrolyte 680 comprises one or more additives, such as a leveler, a suppressor, and an accelerator, particulates for co-deposition (e.g., nanoparticles and microparticles such as diamond particles, tungsten-carbide particles, chromium-carbide particles, and silicon-carbide particles).

Returning to the example shown in FIG. 6D, cations (e.g., metal cations are combined with electrons, which are supplied to build plate 650 thereby forming the material (e.g., copper deposit). As noted above, the charge balance within electrolyte 680 is maintained by protons generated at the printhead 610. It should be noted that only a set of activated electrodes (illustrated in black color) can be activated during this ECAM process resulting in electrolytic deposit/material formed on a corresponding portion of build plate 650. This corresponding portion is aligned with the activated electrode while the remaining portion of electrodes (inactive electrodes) remains free of electrolytic deposit. This selective deposition is a core ECAM feature provided by selective control of the current passing through the activated electrodes.

Specifically, in some examples, an ECAM system 600 comprises a build plate 650 and a printhead 610 comprising a set of pixelated electrodes 620 and electrode-array drivers 616, such that each of the electrode-array drivers 616 is configured to control a current flow through a corresponding electrode in the set of pixelated electrodes 620. The ECAM system 600 also comprises a position actuator 602 for controlling the position of the build plate 650 relative to the printhead 610 and a power supply 604 connected to the build plate 650 and each of the electrode-array drivers 616. Furthermore, the ECAM system 600 comprises a system controller 606 communicatively coupled to each of the electrode-array drivers 616, the position actuator 602, and the power supply 604. The system controller 606 is configured to store various deposition parameters, e.g., which are developed based on the configuration of the heat exchanger 100. During this operation, a subset of pixelated electrodes 621 is selectively activated from the set of pixelated electrodes 620 according to the deposition parameters thereby causing an ionic flow through an electrolyte 680 provided between at least the subset of pixelated electrodes 621 and the printhead 610. Furthermore, the system controller 606 is configured to (c) instruct the power supply 604 and the electrode-array drivers 616 to map the deposited layer 655 by applying a mapping voltage to each pixelated electrode in the subset of pixelated electrodes 621 and monitoring a current through each pixelated electrode in the subset of pixelated electrodes 621. In some examples, such a mapping process may be used to register the horizontal (left, right) position of the build plate 650 relative to the printhead 610 based on the shape and/or features of the build plate 650. As noted elsewhere, the current through each pixelated electrode in the subset of pixelated electrodes 621 depends on a vertical positional relationship (e.g., the gap) between each pixelated electrode in the subset of pixelated electrodes 621 and the deposited layer 655.

### CONCLUSION

Although the foregoing concepts have been described in some detail for purposes of clarity of understanding, it will be apparent that certain changes and modifications may be practiced within the scope of the appended claims. It should be noted that there are many alternative ways of implementing processes, systems, and apparatuses. Accordingly, the present embodiments are to be considered illustrative and not restrictive.

1. A heat exchanger for use on a heat source, the heat exchanger comprising:
a support structure and a conductive seed layer having a different composition than the support structure and forming a heat-transferring surface on the heat source;
a heat-exchanging portion comprising heat transfer extensions, wherein:
the heat transfer extensions comprise first extension ends, second extension ends, and sidewalls extending between the first extension ends and the second extension ends and forming an opening for circulating a heat transfer fluid through the heat exchanger, and
the first extension ends are electrochemically deposited to the heat-transferring surface and form a heat-exchanging surface.

2. The heat exchanger of claim 1, wherein any dimension of each of the first extension ends within a plane of the heat-exchanging surface is less than a critical dimension, determined by calculating adhesion between the first extension ends and the heat-transferring surface, a coefficient of thermal expansion (CTE) of the heat source at the heat-transferring surface, a coefficient of thermal expansion (CTE) of the heat transfer extensions at the first extension ends, and a design temperature fluctuation for the heat exchanger.

3. The heat exchanger of claim 1, wherein the heat-exchanging portion comprises copper.

4. The heat exchanger of claim 1, wherein the heat-exchanging portion comprises a uniform material composition.

5. The heat exchanger of claim 1, wherein a material composition of the heat transfer extensions varies between the first extension ends and the second extension ends.

6. The heat exchanger of claim 5, wherein the material composition of the heat transfer extensions gradually changes between the first extension ends and the second extension ends.

7. The heat exchanger of claim 5, wherein the material composition of the heat transfer extensions changes in a step fashion between the first extension ends and the second extension ends.

8. The heat exchanger of claim 1, wherein the heat-exchanging portion and the conductive seed layer have same material composition.

9. The heat exchanger of claim 1, wherein the heat-exchanging portion and the conductive seed layer have different material composition.

10. The heat exchanger of claim 1, wherein the support structure comprises tungsten.

11. The heat exchanger of claim 10, wherein the support structure further comprises copper, forming an alloys with tungsten.

12. The heat exchanger of claim 1, wherein the heat source is selected from the group consisting of a central processing unit (CPU), a graphical processing unit (GPU), an application-specific integrated circuit (ASIC), a field-programmable gate array (FPGA), a chipset, a power amplifier, a memory module, and a power management integrated circuit (IC).

13. The heat exchanger of claim 1, wherein the conductive seed layer has a thickness of less than 10 micrometers.

14. The heat exchanger of claim 2, wherein the critical dimension is less than 100 micrometers.

15. The heat exchanger of claim 1, wherein:
the heat transfer extensions comprise first extension ends for attaching the heat exchanger to the heat source,
the first extension ends are separated by gaps providing access to the opening and positioned within a plane defined by the first extension ends, and
an area ratio of the first extension ends to the gaps is less than 25%.

16. The heat exchanger of claim 1, wherein the heat-exchanging portion further comprises an interconnecting bridge electrochemically deposited onto each of the second extension ends while partially enclosing the opening.

17. The heat exchanger of claim 1, wherein the first extension ends have a cross-sectional shape within a plane of the heat-exchanging surface selected from the group consisting of an oval, a rectangle, a trapezoid, and a triangle.

18. The heat exchanger of claim 1, wherein the first extension ends and the second extension ends have a same shape.

19. The heat exchanger of claim 1, wherein the first extension ends and the second extension ends have a same size.

20. The heat exchanger of claim 1, wherein the first extension ends have smaller sizes than the second extension ends.
